(19) United States
(12) Patent Application Publication
(10) Pub. No.: US 2012/0170185 A1
(43) Pub. Date: Jul. 5, 2012

(54) DISPLAY MODULE MOUNTING STRUCTURE AND ELECTRONIC DEVICE USING THE SAME

(76) Inventor: Tzu-Chih LIN, Hsinchu Country (TW)

(21) Appl. No.: 13/177,294

(22) Filed: Jul. 6, 2011

(30) Foreign Application Priority Data
Dec. 31, 2010 (TW) 099147419

(51) Int. Cl. H05K 7/00

(52) U.S. Cl. 361/679.01

(57) ABSTRACT

A display module mounting structure and an electronic device using same are disclosed. The display module mounting structure includes a display module having a display element and a frame fitted around the display element; and an electronic device main body having a holding seat and a first supporting member. The holding seat is extended along a part of an outer periphery of the electronic device main body to have a U-shaped configuration for holding the display module therein with an inner wall surface fitly bearing on an outer periphery of the frame of the display module. The first supporting member is extended along a lower inner wall surface of the holding seat to protrude into a space defined in the holding seat for supporting the frame of the display module thereon, so that a clearance is formed between the display element and the electronic device main body.

### FIELD OF THE INVENTION

The present invention relates to a display module mounting structure, and more particularly to a display module mounting structure including a plastic supporting member integrally formed with an electronic device main body to replace the conventional independently formed metal support in the electronic device.

### BACKGROUND OF THE INVENTION

Most of the currently available electronic devices with display module include an independently provided metal support for a display to mount thereon. The metal support has a bottom and a peripheral wall perpendicularly rising from an outer periphery of the bottom to define a receiving space therein. The display is disposed in the receiving space, and one side of the bottom opposite to the display faces toward a circuit board of the electronic device.

The conventional metal support is provided on the peripheral wall at one side facing away from the display with a plurality of supporting legs, which are pressed against and fixed to the electronic device for supporting the display above the circuit board. With these arrangements, the display is not directly pressed against the circuit board of the electronic device to thereby protect the display and circuits on the circuit board against damage.

However, due to the drastically increased metal material price and the high energy cost in recent years, even if the metal support for supporting the display above the circuit board provides good supporting strength and reliability, its high production cost forms a heavy burden to the electronic device manufacturers. Further, in addition to the high metal material cost, the independently produced metal support for supporting the display also requires additional procedures for material purchasing, product manufacturing and assembling. And, for the manufacturers, the increased material cost and the increased manufacturing and assembling procedures all are disadvantageous factors to the production.

It is therefore necessary to develop a display module mounting structure that can be produced with simplified manufacturing and assembling procedures at reduced material cost, so as to replace the conventional metal display support and overcome the drawbacks thereof, allowing the manufacturers to have gains from the convenient manufacturing process and reduced cost, and accordingly upgraded product competing ability in the market.

### SUMMARY OF THE INVENTION

A primary object of the present invention is to provide a display module mounting structure to overcome the problems of increased manufacturing cost and complicated assembling procedures that occurred in using the conventional metal-made display support in an electronic device with display.

To achieve the above and other objects, the display module mounting structure according to the present invention is applicable to an electronic device with display, and includes a display module and an electronic device main body. The display module includes at least a display element and a frame fitted around the display element. The electronic device main body includes a holding seat and a first supporting member. The holding seat is extended along a part of an outer periphery of the electronic device main body to have a U-shaped configuration for holding the display module therein while an inner wall surface of the holding seat fitly bears on an outer periphery of the frame of the display module. The first supporting member is extended along a lower inner wall surface of the holding seat to protrude into a space defined in the holding seat for supporting the frame of the display module thereon, so that a clearance is formed between the display element and one side of the electronic device main body facing toward the display element.

The display module mounting structure further includes a first cover member connected to a first side of the electronic device main body corresponding to the holding seat and the display module held in the holding seat. The first cover member has an opening correspondingly aligned with the display element, and portions of the first cover member adjoining an outer periphery of the opening are rest on a top of the holding seat. The first cover member further includes a second supporting member, which is located to one side of the opening to correspond to an open end of the U-shaped holding seat, such that the second supporting member is pressed against the electronic device main body when the first cover member is closed onto the first side of the electronic device main body.

The display module mounting structure further includes a second cover member connected to a second side of the electronic device main body opposite to the first cover member and correspondingly connected to the first cover member. The first cover member further includes at least one retaining member located on an outer periphery of the first cover member and provided with a first stop hole, and the second cover member is formed on an outer periphery with at least one second stop hole corresponding to the at least one first stop hole. When the first cover member and the second cover member are correspondingly closed to each other, a fastening element can be screwed through the aligned first and second stop holes to firmly and tightly connect the first and the second cover member to each other, so that the electronic device main body and the display module are enclosed in between the first and second cover members.

The display module further includes at least one signal cable, and the signal cable is connected to the electronic device main body via the clearance.

In a preferred embodiment of the present invention, the holding seat and the first supporting member are made of a rigid plastic material.

To achieve the above and other objects, the electronic device with display module mounting structure according to the present invention includes a display module including at least a display element and a frame fitted around outer edges of the display element; an electronic device main body including a holding seat and a first supporting member, the holding seat being extended along part of an outer periphery of the electronic device main body to thereby have a substantially U-shaped configuration for holding the display module therein with an inner wall surface of the holding seat fitly bearing on an outer periphery of the frame of the display module, and the first supporting member being extended along a lower inner wall surface of the holding seat to protrude into a space defined in the holding seat for supporting the frame of the display module thereon, so that a clearance is formed between the display element and one side of the electronic device main body facing toward the display element; a first cover member connected to a first side of the electronic device main body corresponding to the holding seat and the display module held in the holding seat, the first cover member having an opening correspondingly aligned with the display element, and portions of the first cover member adjoining an outer periphery of the opening being rest on a top of the holding seat; and a second cover member connected to a second side of the electronic device main body opposite to the first cover member and correspondingly connected to the first cover member, and the first and the second cover member being firmly and tightly connected to each other to enclose the electronic device main body and the display module therebetween.

The first cover member of the electronic device further includes a second supporting member, which is located to one side of the opening to correspond to an open end of the U-shaped holding seat, such that the second supporting member is pressed against the electronic device main body when the first cover member is closed onto the first side of the electronic device main body.

According to a preferred embodiment of the electronic device, the holding seat and the first supporting member are made of a rigid plastic material.

With the above arrangements, the display module mounting structure and the electronic device using same according to the present invention have one or more of the following advantages:

(1) The holding seat and the first supporting member of the display module mounting structure are made of a rigid plastic material to replace the conventional metal-made display support to thereby largely save the expensive material cost of the metal display support and omit the procedures for producing the metal support, enabling a largely reduced manufacturing cost of the electronic device.

(2) The holding seat and the first supporting member of the display module mounting structure are integrally formed with the electronic device main body to save the procedure of assembling the supporting member to the electronic device main body, and the display module can be directly disposed in the holding seat to simplify the procedures for product assembling and production management and minimize the errors in the products.

(3) The display module mounting structure further includes the second supporting member to provide reinforced supporting strength, ensuring that the display module is not in contact with the electronic device main body and accordingly increasing the reliability of the products.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of a display module mounting structure according to an embodiment of the present invention;

FIG. 2 is an exploded perspective view of an electronic device with display module mounting structure according to an embodiment of the present invention; and

FIG. 3 is a cutaway view of the electronic device with display module mounting structure according to the present invention.

### DETAILED DESCRIPTION OF THE PREFERRED EMBODIMENTS

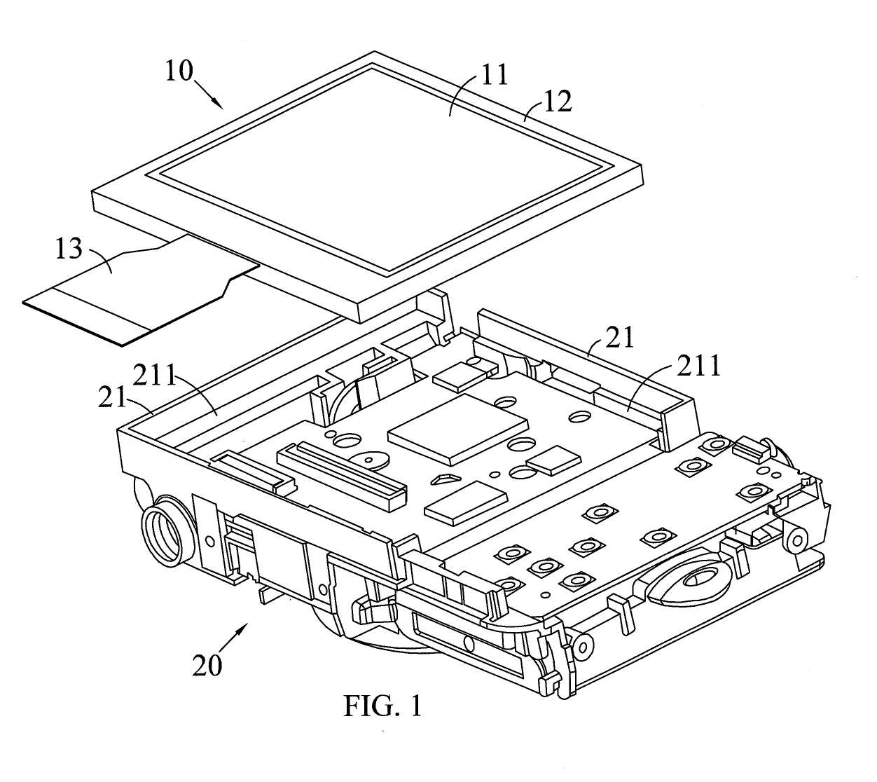

Please refer to FIG. 1 that is an exploded perspective view of a display module mounting structure according to an embodiment of the present invention. As shown, the display module mounting structure includes a display module 10 and an electronic device main body 20. The display module 10 includes a display element 11, a frame 12, and a signal cable 13. The frame 12 is fitted around outer edges of the display element 11, and the signal cable 13 provided to one side of the frame 12.

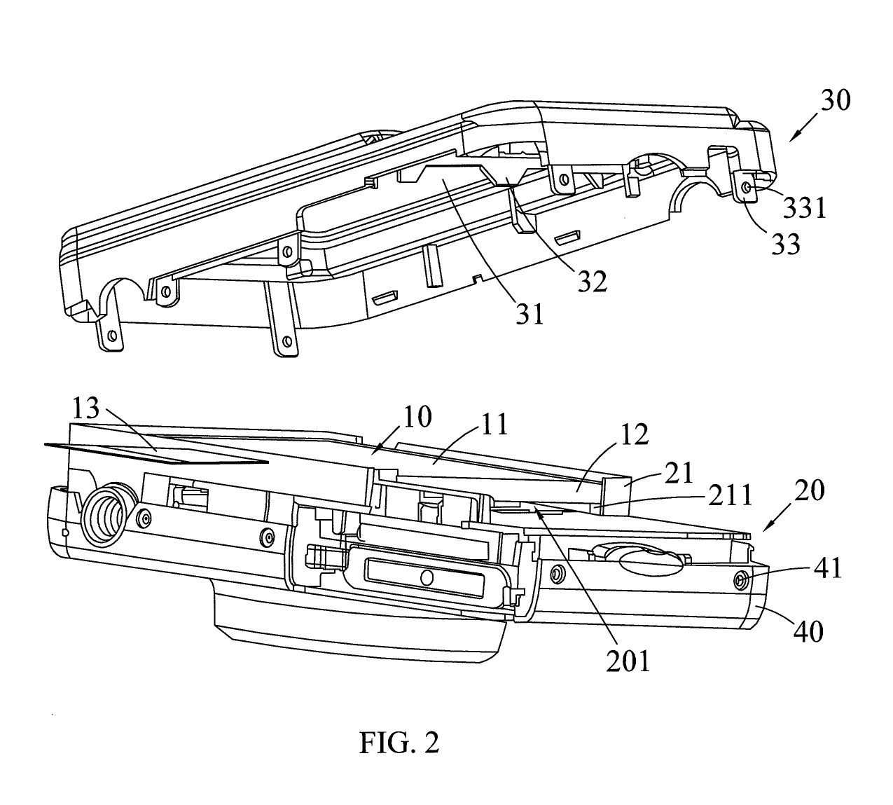

The electronic device main body 20 includes a holding seat 21 and a first supporting member 211. The holding seat 21 is extended along part of an outer periphery of the electronic device main body 20 to thereby have a substantially U-shaped configuration. The first supporting member 211 is extended along a lower inner wall surface of the holding seat 21 to protrude into a space defined in the holding seat 21. With these arrangements, the display element 11 and the frame 12 of the display module 10 can be disposed in the holding seat 21, such that the frame 12 is supported on the first supporting member 211 with an outer periphery of the frame 12 fitly bearing on an inner wall surface of the holding seat 21. In this manner, a clearance 201 is formed between the display element 11 and the electronic device main body 20, as shown in FIG. 2.

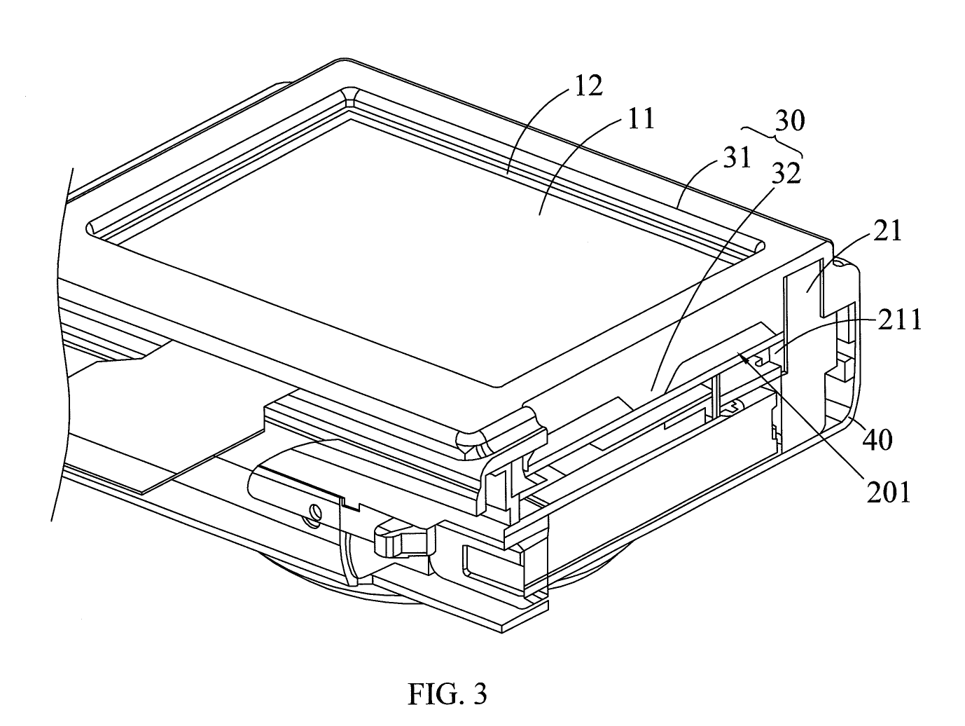

Please refer to FIGS. 2 and 3. FIG. 2 is an exploded perspective view of an electronic device with display module mounting structure according to an embodiment of the present invention, and FIG. 3 is a cutaway view of the electronic device with display module mounting structure according to the present invention. As shown, a first cover member 30 is connected to a first side of the electronic device main body 20, and a second cover member 40 is connected to a second side of the electronic device main body 20 opposite to the first cover member 30.

The first cover member 30 is formed with an opening 31, a second supporting member 32, and at least one retaining member 33. The opening 31 is corresponding to and aligned with the display element 11, and portions of the first cover member 30 adjoining an outer periphery of the opening 31 are rest on a top of the holding seat 21. The second supporting member 32 is located to one side of the opening 31 to correspond to an open end of the U-shaped holding seat 21, such that the second supporting member 32 is pressed against the electronic device main body 20 when the first cover member 30 is closed onto the first side of the electronic device main body 20. The at least one retaining member 33 is provided on an outer periphery of the first cover member 30 and is provided with a first stop hole 331. The second cover member 40 is formed on an outer periphery with at least one second stop hole 41 corresponding to the at least one first stop hole 331. When the first cover member 30 and the second cover member 40 are correspondingly closed to each other, a fastening element (not shown) can be screwed through the aligned first and second stop holes 331, 41 to firmly and tightly connect the first and the second cover member 30, 40 to each other, so that the electronic device main body 20 and the display module 10 are enclosed in between the first and second cover members 30, 40 and restrained from moving, and the signal cable 13 is connected to the electronic device main body 20 via the clearance 201 (not shown). In an embodiment of the present invention, the fastening element for locking the first cover member 30 to the second cover member 40 can be a screw without being limited thereto.

In an embodiment of the present invention, the holding seat 21 and the first supporting member 211 are made of a rigid plastic material without being limited thereto. That is, in other embodiments, the holding seat 21 and the first supporting member 211 can also be made of other non-metal rigid materials to replace the conventional metal-made display support, so as to largely reduce the manufacturing cost of the electronic devices with display module.

With the display module mounting structure according to the present invention, the holding seat 21 and the first supporting member 211 can be integrally formed with the electronic device main body 20, and the display module 10 can be directly disposed in the holding seat 21 and assembled to the electronic device main body 20 to largely simplify the assembling and management procedures for producing the electronic devices with display module.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A display module mounting structure for fixing a display module in an electronic device, comprising:
a display module including at least a display element and a frame; and the frame being fitted around outer edges of the display element; and
an electronic device main body including:
a holding seat for holding the display module therein; the holding seat being extended along part of an outer periphery of the electronic device main body to thereby have a substantially U-shaped configuration, and having an inner wall surface fitly bearing on an outer periphery of the frame of the display module; and
a first supporting member being extended along a lower inner wall surface of the holding seat to protrude into a space defined in the holding seat for supporting the frame of the display module thereon, so that a clearance is formed between the display element and one side of the electronic device main body facing toward the display element.

2. The display module mounting structure as claimed in claim 1, further comprising a first cover member being connected to a first side of the electronic device main body corresponding to the holding seat and the display module held in the holding seat; the first cover member having an opening correspondingly aligned with the display element, and portions of the first cover member adjoining an outer periphery of the opening being rest on a top of the holding seat.

3. The display module mounting structure as claimed in claim 2, wherein the first cover member further includes a second supporting member, which is located to one side of the opening to correspond to an open end of the U-shaped holding seat, such that the second supporting member is pressed against the electronic device main body when the first cover member is closed onto the first side of the electronic device main body.

4. The display module mounting structure as claimed in claim 2, further comprising a second cover member being connected to a second side of the electronic device main body opposite to the first cover member and correspondingly connected to the first cover member.

5. The display module mounting structure as claimed in claim 4, wherein the first cover member further includes at least one retaining member located on an outer periphery of the first cover member and provided with a first stop hole, and the second cover member is formed on an outer periphery with at least one second stop hole corresponding to the at least one first stop hole; whereby when the first cover member and the second cover member are correspondingly closed to each other, a fastening element can be screwed through the aligned first and second stop holes to firmly and tightly connect the first and the second cover member to each other, so that the electronic device main body and the display module are enclosed in between the first and second cover members.

6. The display module mounting structure as claimed in claim 1, wherein the display module further includes at least one signal cable, and the signal cable is connected to the electronic device main body via the clearance.

7. The display module mounting structure as claimed in claim 1, wherein the holding seat and the first supporting member are made of a rigid plastic material.

8. An electronic device with display module mounting structure, comprising:
a display module including at least a display element and a frame, and the frame being fitted around outer edges of the display element;
an electronic device main body including:
a holding seat for holding the display module therein; the holding seat being extended along part of an outer periphery of the electronic device main body to thereby have a substantially U-shaped configuration, and having an inner wall surface fitly bearing on an outer periphery of the frame of the display module; and
a first supporting member being extended along a lower inner wall surface of the holding seat to protrude into a space defined in the holding seat for supporting the frame of the display module thereon, so that a clearance is formed between the display element and one side of the electronic device main body facing toward the display element;
a first cover member being connected to a first side of the electronic device main body corresponding to the holding seat and the display module held in the holding seat; the first cover member having an opening correspondingly aligned with the display element, and portions of the first cover member adjoining an outer periphery of the opening being rest on a top of the holding seat; and
a second cover member being connected to a second side of the electronic device main body opposite to the first cover member and correspondingly connected to the first cover member; and the first and the second cover member being firmly and tightly connected to each other to enclose the electronic device main body and the display module therebetween.

9. The electronic device with display module mounting structure as claimed in claim 8, wherein the first cover member further includes a second supporting member, which is located to one side of the opening to correspond to an open end of the U-shaped holding seat, such that the second supporting member is pressed against the electronic device main body when the first cover member is closed onto the first side of the electronic device main body.

10. The electronic device with display module mounting structure as claimed in claim 8, wherein the holding seat and the first supporting member are made of a rigid plastic material.
